(19) United States
(12) Patent Application Publication
(10) Pub. No.: US 2026/0303090 A1
(43) Pub. Date: Oct. 1, 2026

(54) TRANSMITTER CIRCUIT

(71) Applicants: Chune Chang, Pingtung County (TW); Pen-Jui Peng, Taoyuan City (TW)

(72) Inventors: Chune Chang, Pingtung County (TW); Pen-Jui Peng, Taoyuan City (TW)

(73) Assignee: ITE Tech. Inc., Hsinchu (TW)

(21) Appl. No.: 19/207,400

(22) Filed: May 14, 2025

(30) Foreign Application Priority Data
Mar. 26, 2025 (TW) 114111518

(51) Int. Cl. H03K 17/687; H03H 11/28

(52) U.S. Cl. CPC H03K 17/6871; H03H 11/28

(57) ABSTRACT

A transmitter circuit includes an impedance adjusting circuit and multiple driver circuits. The impedance adjusting circuit includes a first impedance adjusting circuit and a second impedance adjusting circuit. The first impedance adjusting circuit includes a first replica driving unit, and is configured to control an output impedance of the first replica driving unit to a first impedance value. The second impedance adjusting circuit includes a second replica driving unit, and is configured to control an output impedance of the second replica driving unit to a second impedance value different from the first impedance value. The driving units respectively includes multiple standard driving units. Each standard driving unit is configured to receive a corresponding one of a first impedance adjusting signal and a second impedance adjusting signal to be set at a first impedance value or a second impedance value.

### CROSS-REFERENCE TO RELATED APPLICATION

This application claims the priority benefit of Taiwan application serial no. 114111518 filed on Mar. 26, 2025. The entirety of the above-mentioned patent application is hereby incorporated by reference herein and made a part of this specification.

### BACKGROUND

### Technical Field

The disclosure relates to a circuit, and in particular to a transmitter circuit.

### Related Art

With the popularity of portable electronic devices, how to effectively reduce the usage area and cost of semiconductor devices has become an important issue when designing circuits.

### SUMMARY

The disclosure provides a transmitter circuit, which may effectively reduce manufacturing cost of the transmitter circuit.

A transmitter circuit of the disclosure includes an impedance adjusting circuit and multiple driver circuits. The impedance adjusting circuit includes a first impedance adjusting circuit and a second impedance adjusting circuit. The first impedance adjusting circuit includes a first replica driving unit, and is configured to control an output impedance of the first replica driving unit to a first impedance value through a first impedance adjusting signal. The second impedance adjusting circuit includes a second replica driving unit, and is configured to control the output impedance of the second replica driving unit to a second impedance value through a second impedance adjusting signal. The second impedance value is different from the first impedance value. The driver circuits respectively have multiple standard driving units. Each standard driving unit is configured to receive a corresponding one of the first impedance adjusting signal and the second impedance adjusting signal to be set to the first impedance value or the second impedance value.

Based on the above, the transmitter circuit of the disclosure may reduce the manufacturing cost of the transmitter circuit through the use of the first standard driving unit and the second standard driving unit.

### BRIEF DESCRIPTION OF THE DRAWINGS

FIG. 1 is a circuit block diagram of a transmitter circuit according to an embodiment of the disclosure.

FIG. 2A is a circuit diagram of a driver circuit according to an embodiment of the disclosure.

FIG. 2B is a circuit diagram of a driver circuit according to an embodiment of the disclosure.

FIG. 3A is a circuit diagram of a first impedance adjusting circuit according to an embodiment of the disclosure.

FIG. 3B is a circuit diagram of a second impedance adjusting circuit according to an embodiment of the disclosure.

### DESCRIPTION OF THE EMBODIMENTS

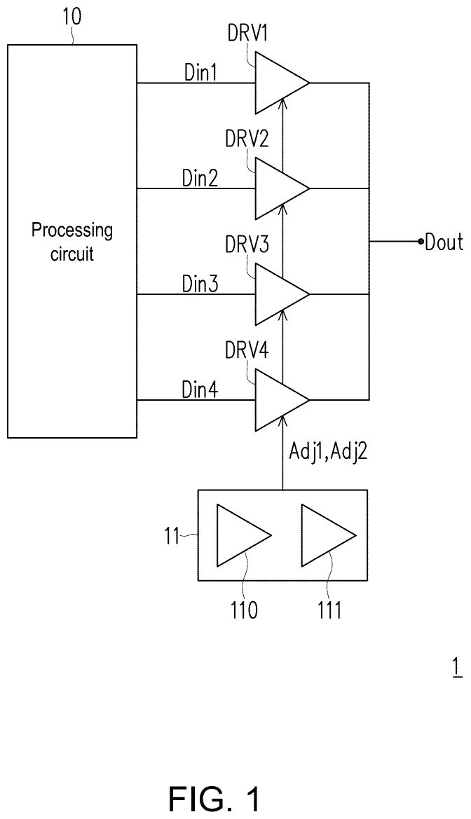

FIG. 1 is a circuit block diagram of a transmitter circuit 1 according to an embodiment of the disclosure. A transmitter circuit 1 includes a processing circuit 10, driver circuits DRV1 to DRV4, and an impedance adjusting circuit 11. Generally, to simplify the design, the driver circuits DRV1 to DRV4 are designed in a modular form. That is, the driver circuits DRV1 to DRV4 are implemented based on the same standard driving unit. Each of the driver circuit DRV1 to DRV4 may be connected in parallel to a corresponding number of standard driving units according to the amplitude requirements of each channel, thereby satisfying driving requirements of the transmitter circuit 1. In this embodiment, although not explicitly drawn, two different sizes of standard driving units are used in the driver circuits DRV1 to DRV4 for driving. A circuit impedance value of a first type standard driving unit may be, for example, a preset standard impedance value, while a circuit impedance value of a second type standard driving unit may be equivalent to an impedance value of a predetermined number of the first type standard driving units connected in parallel. In this way, by implementing the driver circuits DRV1 to DRV4 with two types of the standard driving units having different impedance values, in situations where a large number of standard driving units need to be connected in parallel in the driver circuits DRV1 to DRV4, the number of standard driving units connected in parallel and the manufacturing cost may be effectively reduced.

Specifically, the processing circuit 10 may be configured to perform operations such as computation or coding on the data to be transferred, thereby generating output driving signals Din1 to Din4. In some embodiments, the processing circuit 10 may include circuits such as a pseudo random bit sequence (PRBS) circuit, an encoder, a multiplexer, and a filter. The driver circuits DRV1 to DRV4 may receive the output driving signals Din1 to Din4, output signals with appropriate amplitude according to driving of a first impedance adjusting signal Adj1 and a second impedance adjusting signal Adj2 provided by the impedance adjusting circuit 11, and collectively form an output signal Dout at an output terminal.

The impedance adjusting circuit 11 includes a first impedance adjusting circuit 110 and a second impedance adjusting circuit 111. The first impedance adjusting circuit 110 includes a first replica driving unit (not shown in FIG. 1). The first impedance adjusting circuit 110 may control an output impedance of the first replica driving unit to a first impedance value by generating a first impedance adjusting signal Adj1. The second impedance adjusting circuit 111 includes a second replica driving unit (not shown in FIG. 1). The second impedance adjusting circuit 111 may control an output impedance of the second replica driving unit to a second impedance value by generating a second impedance adjusting signal Adj2. Since the first replica driving unit and the second replica driving unit are replica circuits of the first standard driving unit and the second standard driving unit respectively, the second replica driving unit is equivalently a parallel circuit of multiple first replica driving units. Therefore, the second impedance value set by the second impedance adjusting circuit is smaller than the first impedance value set by the first impedance adjusting circuit. In some embodiments, the first impedance value may be twenty-one times the second impedance value. However, depending on different design requirements, a ratio between the first impedance value and the second impedance value may be adaptively adjusted. Alternatively, there may be more than one type of replica driving unit, all of which fall within the scope of the variations of embodiments disclosed herein.

Specifically, the first impedance adjusting circuit 110 includes a first replica driving unit, and the second impedance adjusting circuit 111 includes a second replica driving unit, with the circuit structure and size of the two types of replica driving units being identical to those of the first standard driving unit and the second standard driving unit configured to implement the driver circuits DRV1 to DRV4. The first impedance adjusting circuit 110 and the second impedance adjusting circuit 111 may generate the first impedance adjusting signal Adj1 and the second impedance adjusting signal Adj2 respectively, to control the output impedance of the first replica driving unit and the second replica driving unit to a preset first impedance value and a preset second impedance value respectively. In this way, the impedance adjusting circuit 11 may provide the first impedance adjusting signal Adj1 and the second impedance adjusting signal Adj2 to the corresponding first standard driving unit and second standard driving unit of the driver circuits DRV1 to DRV4, so that the first standard driving unit and the second standard driving unit also have the first impedance value and the second impedance value, allowing the transmitter circuit 1 to perform a preset driving operation.

In some embodiments, the first standard driving unit and the first replica driving unit that receive control from the first impedance adjusting signal Adj1 both have an output impedance with the first impedance value, while the second standard driving unit and the second replica driving unit that receive control from the second impedance adjusting signal Adj2 both have an output impedance with the second impedance value, and naturally, the first impedance value is correspondingly twenty-one times the second impedance value.

In some embodiments, the USB4 transmission standard requires that: the driver circuit DRV1 needs to have the capability to generate amplitude output from 0% to 7.5% of the maximum amplitude, with a resolution of 2.5% of the maximum amplitude; the driver circuit DRV2 needs to have the capability to generate amplitude output from 0% to 25% of the maximum amplitude, with a resolution of 5% of the maximum amplitude; the driver circuit DRV3 needs to have the capability to generate amplitude output from 52.5% to 100% of the maximum amplitude, with a resolution of 2.5% of the maximum amplitude; and the driver circuit DRV4 needs to have the capability to generate amplitude output from 0% to 15% of the maximum amplitude, with a resolution of 5% of the maximum amplitude.

To meet the aforementioned USB4 transmission standard, the driver circuit DRV1 may, for example, include three first standard driving units in parallel, the driver circuit DRV2 may, for example, include ten first standard driving units in parallel, the driver circuit DRV3 may, for example, include one second standard driving unit, and the driver circuit DRV4 may, for example, include six first standard driving units in parallel. In this situation, the first standard driving unit may receive control from the first impedance adjusting signal Adj1 and have a first impedance value, while each first standard driving unit may provide a driving capability of 2.5% of the maximum amplitude. In a situation where the impedance of the second standard driving unit may be equated to the impedance of twenty-one first standard driving units connected in parallel, each second standard driving unit may receive control from the second impedance adjusting signal Adj 2, to provide a driving capability of 52.5% of the maximum amplitude. Therefore, using the second standard driving unit to replace multiple first standard driving units connected in parallel may effectively reduce the manufacturing cost while meeting system requirements.

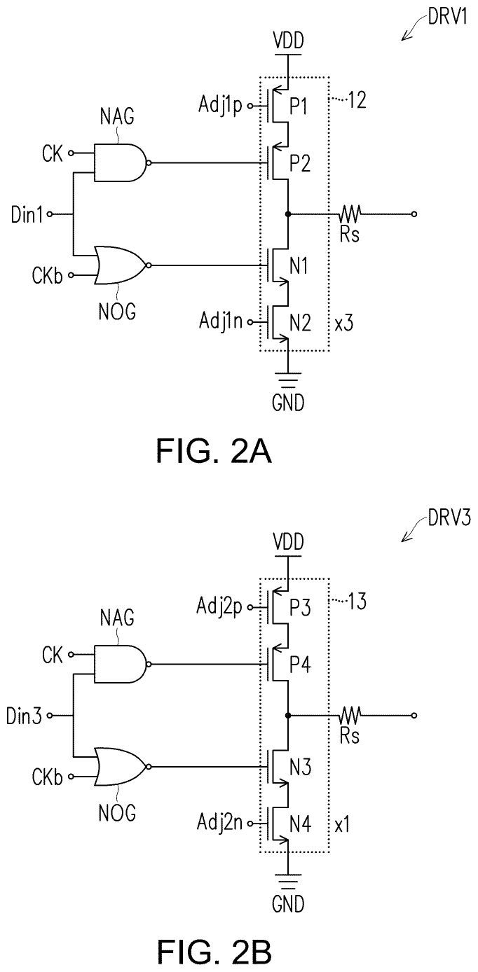

FIG. 2A is a circuit diagram of a driver circuit DRV1 according to an embodiment of the disclosure. As shown in FIG. 2A, the driver circuit DRV1 includes logic gates NAG, NOG and a first standard driving unit 12. In detail, the driver circuit DRV1 may receive gate control from clock signals CK and CKb and data from an input signal Din1 to control the driving of the first standard driving unit 12. In this embodiment, although not explicitly drawn, the driver circuit DRV1 is formed by three first standard driving units 12 in parallel, and collectively coupled to the output terminal through a resistance Rs. In this way, the driving unit DRV1 may provide three times the driving current to the output terminal. In other embodiments, the number of first standard driving units 12 in parallel may of course be adjusted according to design requirements.

In detail, the first standard driving unit 12 includes P-type transistors P1, P2 and N-type transistors N1, N2, which are connected in series between an operating voltage VDD and a ground voltage GND. Gates of transistors P1, N2 respectively receive a first pull-up adjusting signal Adj1p and a first pull-down adjusting signal Adj1n of the first impedance adjusting signal Adj1, and is configured to control the output impedance of the first standard driving unit 12 to a first impedance value.

More specifically, due to a logic relationship of the logic gates NAG, NOG, an upper portion of the first standard driving unit 12 composed of the transistors P1, P2 and an lower portion of the second standard driving unit composed of the transistors N1, N2 may not be turned on simultaneously, the clock signal Ck and the output driving signal may only turn on either the upper portion or the lower portion. Therefore, in order to make the impedance seen at the output terminal of the first standard driving unit equal to the first impedance value, the output impedances of both the upper portion and lower portion of the first standard driving unit 12 may be respectively controlled to the first impedance value by the first pull-up adjusting signal Adj1p and the first pull-down adjusting signal Adj1n of the first adjusting signal Adj1.

FIG. 2B is a circuit diagram of a driver circuit DRV3 according to an embodiment of the disclosure. In this embodiment, the driver circuit DRV3 is formed by one second standard driving unit 13, and collectively coupled to the output terminal through the resistance Rs. The driver circuit DRV3 in FIG. 2B and the driver circuit DRV1 in FIG. 2A, except that in FIG. 2A, three first standard driving units 12 connected in parallel are replaced by one second standard driving unit 13 in FIG. 2B, and the gates of the transistors P3, N4 respectively receive a second pull-up adjusting signal Adj2p and a second pull-down adjusting signal Adj2n of the second impedance adjusting signal Adj2. In this embodiment, the first standard driving unit 12 and the second standard driving unit 13 have the same circuit structure, except that the impedance of the second standard driving unit 13 is the equivalent impedance of twenty-one first standard driving units 12 connected in parallel.

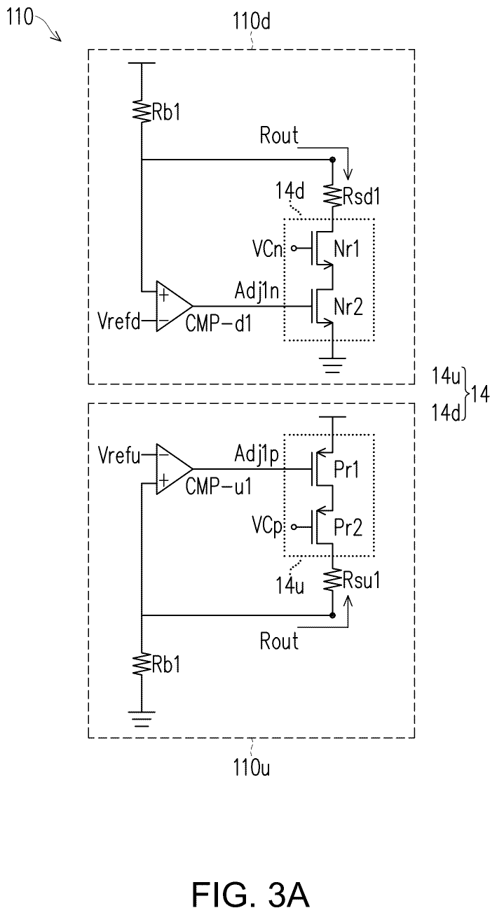

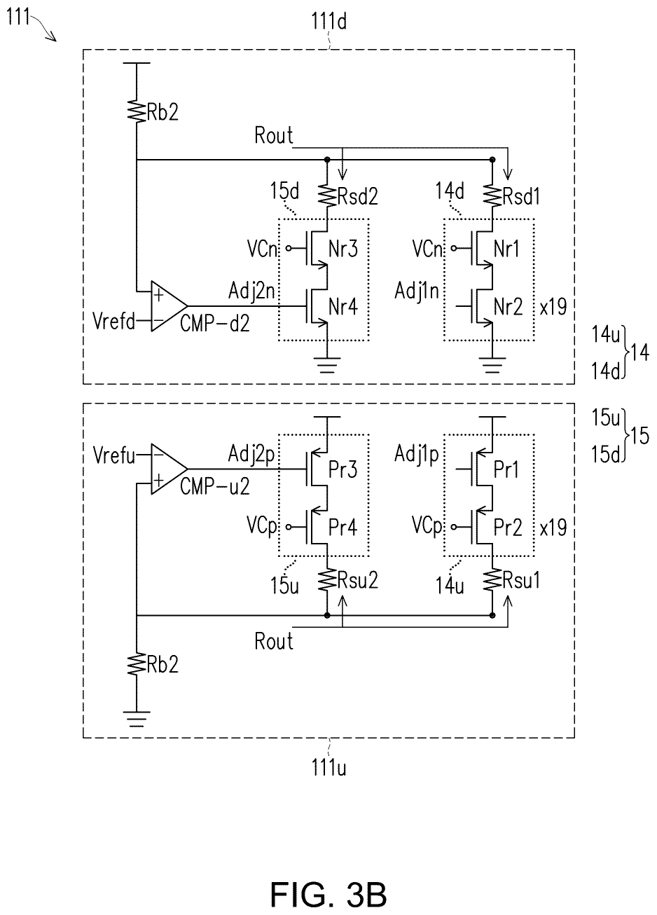

FIG. 3A is a circuit diagram of a first impedance adjusting circuit 110 according to an embodiment of the disclosure. The first impedance adjusting circuit 110 includes a first pull-up adjusting circuit 110u and a first pull-down adjusting circuit 110d. Generally, a first replica driving unit 14 configured to simulate and adjust the first standard driving unit 12 is divided into an upper portion 14u and a lower portion 14d, two of which are respectively placed inside the first pull-up adjusting circuit 110u and the first pull-down adjusting circuit 110d for control and adjustment.

The first pull-up adjusting circuit 110u may generate the first pull-up adjusting signal Adj1u in the first impedance adjusting signal Adj1, to control an output impedance of the upper portion 14u of the first replica driving unit 14 to the first impedance value. Additionally, the first pull-down adjusting circuit 110d includes the lower portion 14d of the first replica driving unit 14. The first pull-down adjusting circuit 110d may generate the first pull-down adjusting signal Adj1d in the first impedance adjusting signal Adj1, to control an output impedance of the lower portion 14d of the first replica driving unit 14 to the second impedance value.

In detail, the first pull-up adjusting circuit 110u includes a first pull-up transistor series and resistances Rsu1, Rb1. The first pull-up transistor series may form the upper portion 14u of the first replica driving unit 14, and includes P-type transistors Pr1, Pr2 connected in series. Overall, the transistors Pr1, Pr2 and the resistances Rsu1, Rb1 are connected in series sequentially between the operating voltage and the ground voltage. A positive input terminal of a comparator CMP-d1 is coupled to a node between the resistances Rsu1, Rb1, and receives a reference voltage Vrefu at a negative input terminal. The comparator CMP-u1 may compare the voltages at the positive and negative input terminals to generate the first pull-up adjusting signal Adj1p to a gate of the transistor Pr1, thereby forming a negative feedback control loop. More specifically, a gate of the transistor Pr2 may receive a turn-on voltage VCp, and the node between the resistances Rsu1, Rb1 may be set as an output node of the first pull-up adjusting circuit 110u, configured to simulate the output impedance from the upper portion of the first standard driving unit 12 through the resistance Rs to the output terminal. The first pull-up adjusting circuit 110u may, through the resistance values and voltage settings of the resistances Rsu1, Rb1 and the reference voltage Vrefu, use the control loop formed by the comparator CMP-u1 to adjust transistor Pr1, so that an output impedance Rout looking upward from the node coupled between the resistances Rsu1, Rb1 of the first pull-up transistor series (that is, the upper portion 14u of the first replica driving unit 14) may be controlled at the first impedance value.

Similarly, the first pull-down adjusting circuit 110d has a circuit structure similar to the first pull-up adjusting circuit 110u but inverted upside down, and the first pull-down adjusting circuit 110d may adjust a resistance value of the transistor Nr2 by generating the first pull-down adjusting signal Adj1n, so that the output impedance of the lower portion 14d of the first replica driving unit 14 is also controlled at the first impedance value. The relevant circuit structure and operation of the first pull-down adjusting circuit 110d should refer to the description content about the first pull-up adjusting circuit 110u in the paragraph above, which is not repeated here.

In some embodiments, the resistance Rb1 may be, for example, 10.8 kilohms, and the output impedance Rout of the first pull-up adjusting circuit 110u and the first pull-down adjusting circuit 110d may be controlled by the first pull-up adjusting signal Adj1p and the first pull-down adjusting signal Adj1 n at a first impedance value of 3.6 kilohms.

FIG. 3B is a circuit diagram of a second impedance adjusting circuit 111 according to a first embodiment of the disclosure. The second impedance adjusting circuit 111 includes a second pull-up adjusting circuit 111u and a second pull-down adjusting circuit 111d. Generally, a second replica driving unit 15 configured to simulate and adjust the second standard driving unit 12 is divided into an upper portion 15u and a lower portion 15d, two of which are respectively placed inside the second pull-up adjusting circuit 111u and the second pull-down adjusting circuit 111d for control and adjustment.

Similar to the first pull-up impedance adjusting circuit 110u in FIG. 3A, the second pull-up impedance adjusting circuit 111u in FIG. 3B includes a second pull-up transistor series and resistances Rsu2, Rb2. The second pull-up transistor series forms the upper portion 15u of the second replica driving unit 15, and has transistors Pr3, Pr4. Moreover, the second pull-up transistor series is connected in series with the resistances Rsu2, Rb2 between the operating voltage and the ground voltage. Similarly, a node between the resistances Rsu2, Rb2 may be set as an output node of the second pull-up impedance adjusting circuit 111u, and the output impedance looking from this node towards the second pull-up transistor series (the upper portion 15u of the second replica driving unit 15) may simulate the output impedance of the upper portion of the second standard driving unit 13. However, different from the first pull-up impedance adjusting circuit 110u, the second pull-up impedance adjusting circuit 111u also includes nineteen first pull-up transistor series (the upper portion 14u of the first replica driving unit 14), connected in parallel with the second pull-up transistor series.

The second pull-up adjusting circuit 111u may generate the second pull-up adjusting signal Adj2u in the second impedance adjusting signal Adj2, to control an output impedance of the upper portion 15u of the second replica driving unit 15 to the second impedance value. Additionally, the second pull-down adjusting circuit 111d includes the lower portion 15d of the second replica driving unit 15. The second pull-down adjusting circuit 111d may generate the second pull-down adjusting signal Adj2d in the second impedance adjusting signal Adj2, to control the output impedance of the lower portion 15d of the second replica driving unit 15 to the second impedance value.

In this embodiment, the transistors Pr3, Pr4 of the second pull-up transistor series are connected in series with the resistances Rsu2, Rb2. Nineteen first pull-up transistor series are connected in parallel with the second pull-up transistor series to the node between the resistances Rsu2, Rb2, and are connected to the ground voltage through the resistance Rb2. A positive input terminal of a comparator CMP-u2 is coupled to the node between the resistances Rsu2, Rb2, and receives a reference voltage Vrefu at the negative input terminal. The comparator CMP-d2 may compare the voltages at the positive and negative input terminals to generate the second pull-up adjusting signal Adj2p and provide the second pull-up adjusting signal Adj2p to a gate of the transistor Pr3.

In terms of operation, the transistor Pr1 of the nineteen first pull-up transistor series receives the first pull-up adjusting signal Adj1p generated by the first pull-up impedance adjusting circuit 110 at the gate, thereby being set to the first impedance value. The comparator CMP-u2 may adjust the output impedance of the second pull-up transistor series to the second impedance value by sensing a voltage between the resistances Rsu2, Rb2. Specifically, since the second pull-up adjusting circuit 111u includes nineteen first pull-up transistor series connected in parallel, the output impedance of each first pull-up transistor series is controlled by the first pull-up adjusting signal Adj1u to the first impedance value. Furthermore, the comparator CMP-u2 may adjust the overall output impedance (including the second pull-up transistor series and nineteen first pull-up transistor series) of the second pull-up adjusting circuit 111u looking upward from that node to one-fortieth of the first impedance value according to the voltage between the resistances Rsu2, Rb2. In this way, the output impedance of the second pull-up transistor series may be equivalently adjusted to the parallel connection of twenty-one first pull-up transistor series with the first impedance value, while the second impedance value of the second pull-up transistor series is one twenty-first of the first impedance value.

In some embodiments, the resistance Rb2 may be, for example, 270 ohms, and the output impedance Rout of the second pull-up adjusting circuit 111u and the second pull-down adjusting circuit 111d may be controlled by the second pull-up adjusting signal Adj2p and the second pull-down adjusting signal Adj1n to 90 ohms, which is one-fortieth of the first impedance value of 3.6 kilohms. Therefore, equivalently, the output impedance of the upper portion 15u and the lower portion 15 of the second replica driving unit 15 may also be correspondingly adjusted to one twenty-first of the first impedance value.

Generally, the impedance value of the transistor may be proportional to or positively correlated with the width and length ratio of the transistor size, so the second pull-up transistor series with the smaller impedance value and transistor width and length ratio may also be designed to have a smaller area, thereby effectively improving the manufacturing cost. Compared to connecting in parallel to multiple first pull-up transistor series with larger sizes, using fewer and smaller second pull-up transistor series may implement equivalent circuits with the same functionality, effectively saving manufacturing area and manufacturing cost in terms of both transistor quantity and transistor size.

Furthermore, since the second impedance adjusting circuit 111 also includes the first replica driving unit, and needs to receive the control of the first impedance adjusting signal Adj1. Therefore, the second impedance adjusting signal Adj2 needs to wait until the first impedance adjusting signal Adj1 gradually converges to a steady state, and then the second impedance adjusting signal Adj2 is gradually locked. Of course, this convergence sequence of the first impedance adjusting signal Adj1 and the second impedance adjusting signal Adj2 corresponds to the circuit structure of the first impedance adjusting circuit 110 and the second impedance adjusting circuit 111 drawn in FIG. 3A and FIG. 3B. In other embodiments, the first impedance adjusting signal Adj1 and the second impedance adjusting signal Adj2 may also have different convergence sequences due to different circuit structures. For example, the second impedance adjusting circuit 111 in FIG. 3B includes nineteen sets of first replica driving units and one set of second replica driving unit connected in parallel, the comparators CMP-u2, CMP-d2 adjust the output impedance to one-fortieth of the first impedance value by sensing the voltage at the output node, thereby obtaining a second replica driving unit that is equivalent to twenty-one sets of first replica driving units in parallel. But in other embodiments, the first replica driving unit of the second impedance adjusting circuit may also be removed, thus having only the second replica driving unit. In this situation, the second impedance adjusting circuit may, through appropriately adjusting the resistance Rb2 or providing other reference voltages to the negative input terminal of the comparator, make the output node of the second impedance adjusting circuit have an appropriate bias voltage, so that the comparators CMP-u2, CMP-d2 may generate the second impedance adjusting signal to adjust the output impedance to one twenty-first of the first impedance value. In this way, the second impedance adjusting signal can converge synchronously with the first impedance adjusting signal, without waiting for the convergence of the first impedance adjusting signal.

In summary, in the transmitter circuit of the disclosure, the driver circuit may be formed by the first standard driving unit and the second standard driving unit which is equivalent to the first standard driving units in parallel. In this way, the circuit that originally requires the first standard driving units in parallel may be replaced with smaller second standard driving units, thereby effectively reducing the manufacturing cost of the transmitter circuit.

What is claimed is:

1. A transmitter circuit, comprising:
an impedance adjusting circuit, comprising:
a first impedance adjusting circuit, comprising a first replica driving unit, and configured to control an output impedance of the first replica driving unit to a first impedance value through a first impedance adjusting signal; and
a second impedance adjusting circuit, comprising a second replica driving unit, and configured to control an output impedance of the second replica driving unit to a second impedance value through a second impedance adjusting signal, wherein the second impedance value is different from the first impedance value; and
a plurality of driver circuits, respectively having a plurality of standard driving units, each standard driving unit being configured to receive a corresponding one of the first impedance adjusting signal and the second impedance adjusting signal to be set to the first impedance value or the second impedance value.

2. The transmitter circuit according to claim 1, wherein the first impedance value is greater than the second impedance value.

3. The transmitter circuit according to claim 2, wherein the first impedance value is twenty-one times the second impedance value.

4. The transmitter circuit according to claim 1, wherein the plurality of driver circuits comprises a first driver circuit and a second driver circuit,
wherein a first standard driving unit of the first driver circuit has the same structure as the first replica driving unit, and the first standard driving unit is configured to receive the first impedance adjusting signal to set an output impedance to the first impedance value, and
wherein a second standard driving unit of the second driver circuit has the same structure as the second replica driving unit, and the second standard driving unit is configured to receive the second impedance adjusting signal to set an output impedance to the second impedance value.

5. The transmitter circuit according to claim 1, wherein the first impedance adjusting circuit comprises:
a first pull-up adjusting circuit, comprising an upper portion of the first replica driving unit, and generating a first pull-up adjusting signal of the first impedance adjusting signal, to control an upper portion impedance of the first replica driving unit to the first impedance value;
and a first pull-down adjusting circuit, comprising a lower portion of the first replica driving unit, and generating a first pull-down adjusting signal of the first impedance adjusting signal, to control a lower portion impedance of the first replica driving unit to the first impedance value.

6. The transmitter circuit according to claim 5, wherein the first pull-up adjusting circuit comprises:
a first pull-up transistor series, forming the upper portion of the first replica driving unit, and having a first transistor connected to an operating voltage and a second transistor connected in series to the first transistor;
a first resistance, coupled between the second transistor and an output terminal of the first pull-up adjusting circuit; and
a second resistance, coupled between the output terminal of the first pull-up adjusting circuit and a ground voltage,
wherein one of the first transistor and the second transistor is controlled by the first pull-up adjusting signal, so that the output impedance looking into the first pull-up transistor series from the output terminal of the first pull-up adjusting circuit is the first impedance value.

7. The transmitter circuit according to claim 6, wherein the first impedance adjusting circuit comprises:
a first comparator, having a first input terminal, a second input terminal, and an output terminal, the first input terminal being coupled to the output terminal of the first pull-up adjusting circuit, the second input terminal being configured to receive a preset voltage, and the first comparator being configured to compare voltages of the first input terminal and the second input terminal, and to generate the first pull-up adjusting signal at the output terminal of the first comparator to the first transistor.

8. The transmitter circuit according to claim 6, wherein the second impedance adjusting circuit comprises:
a second pull-up adjusting circuit, comprising an upper portion of the second replica driving unit, generating a second pull-up adjusting signal of the second impedance adjusting signal, to control an output impedance of the upper portion of the second replica driving unit to the second impedance value, and comprising:
a second pull-up transistor series, forming the upper portion of the second replica driving unit, and having a third transistor connected to the operating voltage and a fourth transistor connected in series to the third transistor, wherein the third transistor is controlled by the second pull-up adjusting signal;
a third resistance, coupled between the fourth transistor and an output terminal of the second pull-up adjusting circuit; and
a fourth resistance, coupled between the output terminal of the second pull-up adjusting circuit and the ground voltage.

9. The transmitter circuit according to claim 8, wherein a width and length ratio of the second pull-up transistor series is smaller than a width and length ratio of the first pull-up transistor series.

10. The transmitter circuit according to claim 8, further comprising:
the first pull-up transistor series, coupled between the operating voltage and the output terminal of the second pull-up adjusting circuit.

11. The transmitter circuit according to claim 10, wherein the second pull-up adjusting circuit comprises nineteen of the first pull-up transistor series connected in parallel between the operating voltage and the output terminal of the second pull-up adjusting circuit.
